(19) United States
(12) Patent Application Publication
(10) Pub. No.: US 2026/0040595 A1
(43) Pub. Date: Feb. 5, 2026

(54) BIPOLAR JUNCTION TRANSISTOR AND METHOD FOR FABRICATING THE SAME

(71) Applicant: UNITED MICROELECTRONICS CORP., Hsin-Chu City (TW)

(72) Inventors: Hao-Ping Yan, Tainan City (TW); Ya-Hsin Huang, Tainan City (TW); Chin-Chia Kuo, Tainan City (TW); Wei-Hsuan Chang, Tainan City (TW); Ming-Hua Tsai, Tainan City (TW)

(73) Assignee: UNITED MICROELECTRONICS CORP., Hsin-Chu City (TW)

(21) Appl. No.: 18/829,149

(22) Filed: Sep. 9, 2024

(30) Foreign Application Priority Data
Aug. 2, 2024 (CN) 202411054720.6

(51) Int. Cl. H01L 29/73; H01L 29/06; H01L 29/66

(52) U.S. Cl. CPC H10D 10/00; H10D 10/01; H10D 62/115

(57) ABSTRACT

A bipolar junction transistor includes an emitter region, a base region, a collector region and a plurality of fin structures. The emitter region is disposed on a substrate. The base region surrounds the emitter region. The collector region surrounds the base region. The plurality of fin structures are disposed in the base region and surround the emitter region, and the plurality of fin structures fixedly extend along a direction and parallel to each other.

### BACKGROUND OF THE INVENTION

### 1. Field of the Invention

The present disclosure relates to the field of semiconductor devices, and more particularly, to a bipolar junction transistor (BJT) and a method for fabricating the same.

### 2. Description of the Prior Art

A BJT is mainly composed of three portions of semiconductor materials with different doping degrees, and the charge flow in the BJT is mainly based on the diffusion and the drift of carriers at the PN junction. Taking an NPN transistor as an example, according to the design, electrons in the emitter region with higher doping degree move to the base region through diffusion. In the base region, electron holes are majority carriers and electrons are minority carriers. Since the base region is very thin, these electrons reach the collector region through drift, which forms the collector current. Therefore, the BJT is classified as a minority carrier device. The BJT is capable of amplifying signals, and have excellent capabilities for power controlling, high-speed operation and durability. Therefore, the BJT is frequently used to form amplifier circuits or to drive apparatus, such as speakers and motors. Moreover, the BJT is widely applied in the products of aerospace engineering, medical equipment and robots. Therefore, how to improve the structure of the current BJT is the goal of the relevant industries.

### SUMMARY OF THE INVENTION

According to an embodiment of the present disclosure, a BJT includes an emitter region, a base region, a collector region and a plurality of fin structures. The emitter region is disposed on a substrate. The base region surrounds the emitter region. The collector region surrounds the base region. The plurality of fin structures are disposed in the base region and surround the emitter region, and the plurality of fin structures fixedly extend along a direction and parallel to each other.

According to another embodiment of the present disclosure, a BJT includes an emitter region, a base region, a collector region, a first isolation structure and a second isolation structure. The emitter region is disposed on a substrate. The base region surrounds the emitter region. The collector region surrounds the base region. The first isolation structure is disposed between the emitter region and the base region. The second isolation structure is disposed between the base region and the collector region, and at least one of the first isolation structure and the second isolation structure includes a step structure.

According to yet another embodiment of the present disclosure, a method for fabricating a BJT includes steps as follows. An emitter region is formed on a substrate. A base region surrounding the emitter region is formed. A collector region surrounding the base region is formed. A plurality of fin structures in the base region and surrounding the emitter region are formed, and the plurality of fin structures fixedly extend along a direction and parallel to each other.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are schematic diagrams showing steps for fabricating a BJT according to one embodiment of the present disclosure.

FIG. 7 is a schematic top view showing the BJT shown in FIG. 6.

FIG. 8 is a schematic cross-sectional view showing a BJT according to another embodiment of the present disclosure.

FIG. 9 is a schematic cross-sectional view showing a BJT according to further another embodiment of the present disclosure.

FIG. 10 is a schematic cross-sectional view showing a BJT according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

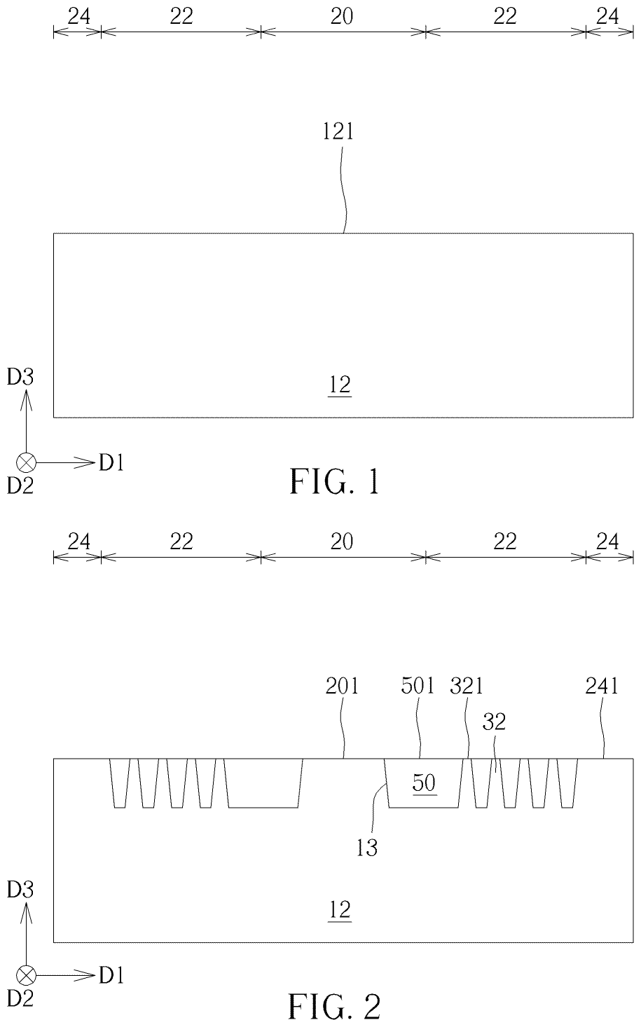

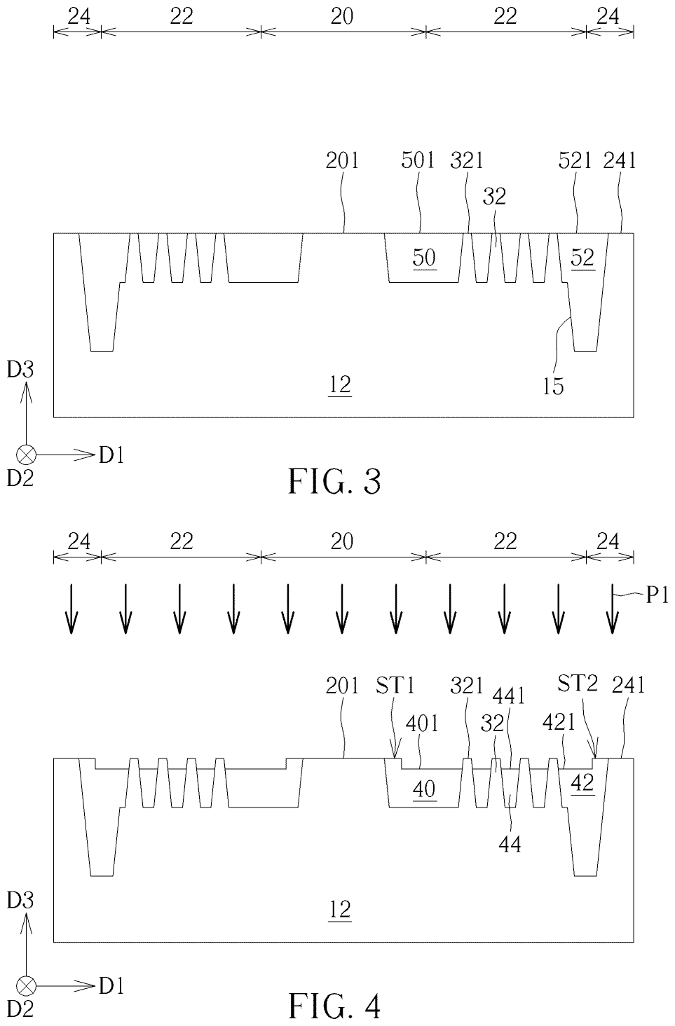

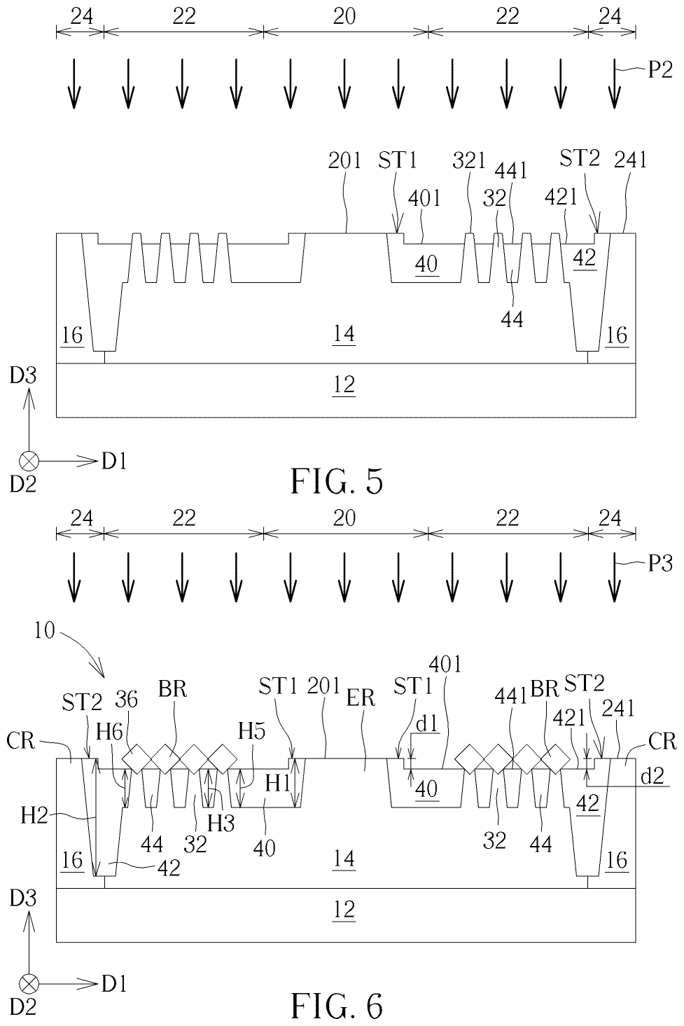

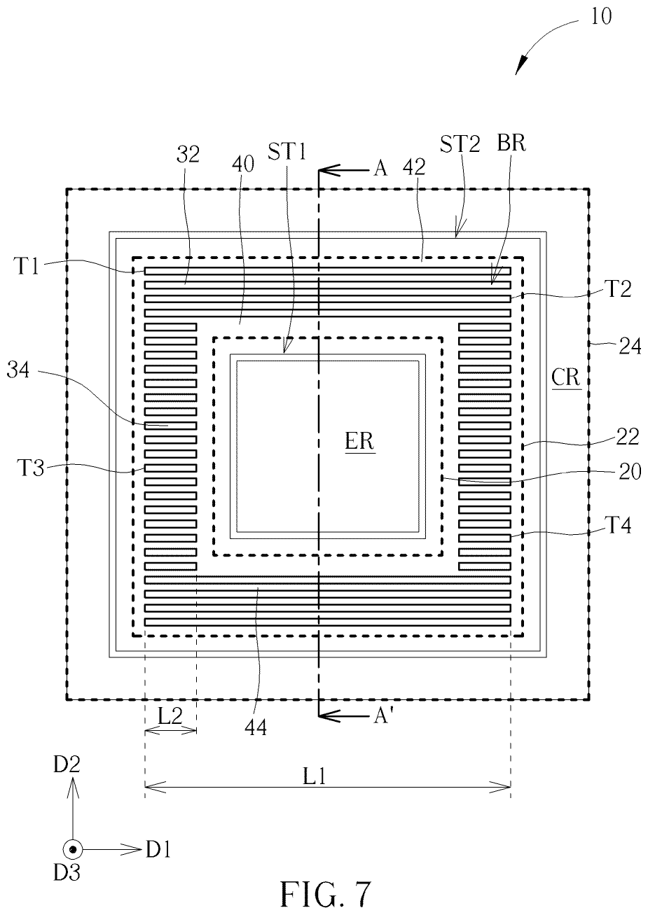

Please refer to FIG. 1 to FIG. 7, in which FIG. 1 to FIG. 6 are schematic cross-sectional views showing steps for fabricating a BJT 10 (see FIG. 6) according to one embodiment of the present disclosure, and FIG. 7 is a schematic top view showing the BJT 10 shown in FIG. 6. For the sake of simplification, the epitaxial structures 36 shown in FIG. 6 are omitted in FIG. 7. In the embodiment, the BJT 10 is exemplary a PNP transistor for explanation. In FIG. 1, a substrate 12 is firstly provided. The substrate 12 may be a doped silicon substrate, a dope epitaxial silicon substrate, a doped silicon carbide substrate or a doped silicon on insulator (SOI) substrate. The dopants of the substrate 12 may be adjusted depending on the subsequently formed BJT 10 being applied to a PNP transistor or an NPN transistor. For example, when the BJT 10 is applied to the PNP transistor, the substrate 12 may be a P-type substrate by implanting P-type dopants, such as boron (B) and indium (In). When the BJT 10 is applied to the NPN transistor, the substrate 12 may be an N-type substrate by implanting N-type dopants, such as arsenic (As) and phosphorus (P). In the embodiment, the BJT 10 is exemplary the PNP transistor. Therefore, the substrate 12 is exemplary the P-type substrate.

The substrate 12 may define a first region 20, a second region 22 and a third region 24 sequentially connected from the inside to the outside. In the top view of the BJT 10 (see FIG. 7), the second region 22 surrounds the first region 20, and the third region 24 surrounds the second region 22. The first region 20 is mainly configured to disposed an emitter region ER, the second region 22 is mainly configured to dispose a base region BR, and the third region 24 is mainly configured to dispose a collector region CR. In the present disclosure, the top view/top viewing angle of the BJT 10 or elements thereof may be, for example, viewing the BJT 10 along a direction opposite to the vertical direction D3. The vertical direction D3 may be, for example, perpendicular to the top surface 121 of the substrate 12.

Next, the emitter region ER (see FIG. 7) is formed on the substrate 12, the base region BR (see FIG. 7) surrounding the emitter region ER is formed, the collector region CR (see FIG. 7) surrounding the base region BR is formed, a plurality of fin structures 32 and 34 (see FIG. 7) in the base region BR and surrounding the emitter region ER are formed, a first isolation structure 40 between the emitter region ER and the base region BR is formed, and a second isolation structure 42 between the base region BR and the collector region CR is formed, which may include steps as follows.

First, as shown in FIG. 2 and FIG. 7, the plurality of fin structures 32 and 34 are formed in the second region 22 of the substrate 12. The fin structures 32 and 34 may be formed by the following method. For example, a patterned mask (not shown) is formed on the substrate 12, and then an etching process is performed to transfer the pattern of the patterned mask to the substrate 12 to form the fin structures 32, 34 and a recess 13. Alternatively, the fin structures 32, 34 and the recess 13 may be formed by a sidewall image transfer (SIT) process, which is well known to those skilled in the art, and the details thereof are omitted herein.

As shown in FIG. 7, the plurality of fin structures 32 and 34 fixedly extend along a first horizontal direction D1 and parallel to each other, and the plurality of fin structures 32 and 34 are spaced apart from each other in the second horizontal direction D2. The aforementioned description of “the plurality of fin structures 32 and 34 fixedly extend along a first horizontal direction D1” may refer that each of the fin structures 32 and 34 substantially has an elongated shape. In the present disclosure, when an element extends along a direction, it may refer that the element has the maximum length in the direction.

Next, as shown in FIG. 2, an isolation structure 50 is formed in the substrate 12 to surround the fin structures 32 and 34. The isolation structure 50 may be formed, for example, by firstly depositing a dielectric material to fill the recess 13, and then removing the portion of the dielectric material protruding from the recess 13 by a planarization process to obtain the isolation structure 50. At this stage, the top surface 501 of the isolation structure 50 is aligned with the top surface 201 of the substrate 12 in the first region 20, the top surface 241 of the substrate 12 in the third region 24, and the top surface 321 of the fin structure 32. Although not shown in the drawings, the top surface 501 of the isolation structure 50 is also aligned with the top surface of the fin structure 34 at this stage.

Next, as shown in FIG. 3, an isolation structure 52 is formed in the substrate 12. The isolation structure 52 is located at the boundary of the second region 22 and the third region 24. The isolation structure 52 may be formed, for example, by firstly forming the recess 15 in the substrate 12, depositing a dielectric material to fill the recess 15, and then removing the portion of the dielectric material protruding from the recess 15 by a planarization process to obtain the isolation structure 52. At this stage, the top surface 521 of the isolation structure 52 is aligned with the top surface 201 of the substrate 12 in the first region 20, the top surface 241 of the substrate 12 in the third region 24, and the top surface 321 of the fin structure 32. Although not shown in the drawings, the top surface 521 of the isolation structure 52 is also aligned with the top surface of the fin structure 34 at this stage. In the embodiment, the isolation structure 50 is firstly formed, and then the isolation structure 52 is formed. However, the present disclosure is not limited thereto. In other embodiments, the isolation structure 52 may be firstly formed, and then the isolation structure 50 is formed. Alternatively, the recess 13 and the recess 15 of different depths may be firstly formed, and then the dielectric material is deposited and the planarization process is performed to form the isolation structures 50 and 52 simultaneously.

Next, as shown in FIG. 4, an etching process P1 may be performed with a patterned mask (not shown) to remove the portions of the isolation structures 50 and 52 exposed from the patterned mask to expose the top portions of the fin structures 32 and 34, to convert the isolation structure 50 located at the boundary of the first region 20 and the second region 22 into the first isolation structure 40, to convert the isolation structure 50 located between any two adjacent ones of the fin structures 32 and 34 into the third isolation structure 44, and to convert the isolation structure 52 located at the boundary of the second region 22 and the third region 24 into the second isolation structure 42. As shown in FIG. 4, the first isolation structure 40 includes a step structure ST1, so that the top surface 401 of the first isolation structure 40 includes two horizontal surfaces instead of a single horizontal surface. In addition, the first isolation structure 40 has different heights in the vertical direction D3. The second isolation structure 42 includes a step structure ST2, so that the top surface 421 of the second isolation structure 42 includes two horizontal surfaces instead of a single horizontal surface. In addition, the second isolation structure 42 has different heights in the vertical direction D3. The third isolation structure 44 does not include the step structure, so that the top surface 441 of the third isolation structure 44 is a single horizontal surface. In addition, the height of the third isolation structure 44 in the vertical direction D3 is substantially fixed. Each of the first isolation structure 40, the second isolation structure 42 and the third isolation structure 44 may be, for example, a shallow trench isolation (ST1), and can provide electrical isolation function between the emitter region ER, the base region BR and the collector region CR formed later. The first isolation structure 40, the second isolation structure 42 and the third isolation structure 44 may include a dielectric material, such as silicon dioxide, but not limited thereto.

Next, as shown in FIG. 5, an ion implantation process P2 is performed together with an annealing process to form the first well region 14 and the second well region 16 in the substrate 12, and to form heavily doped regions (not shown) at the top portions of the substrate 12 in the first region 20 and the third region 24. The dopant concentrations of the heavily doped regions are greater than the dopant concentrations of the first well region 14 and the second well region 16.

Specifically, the ion implantation process P2 may include a first implantation step to implant the dopants with the conductivity type different from that of the substrate 12 into the substrate 12 in the first region 20 and the fin structures 32 and 34 in the second region 22 to form the first well region 14. The ion implantation process P2 may further include a second implantation step to implant the dopants with the conductivity type identical to that of the substrate 12 into the substrate 12 in the third region 24 to form the second well region 16. Preferably, a patterned mask (not shown) is formed to cover the third region 24 when forming the first well region 14. With the shielding of the patterned mask, the dopants with the conductivity type different from that of the substrate 12 is only implanted into the substrate 12 in the first region 20 and the fin structures 32 and 34 in the second region 22 when performing the first implantation step, but not implanted into the substrate 12 in the third region 24. Similarly, a patterned mask (not shown) is formed to cover the first region 20 and the second region 22 when forming the second well region 16. With the shielding of the patterned mask, the dopants with the conductivity type identical to that of the substrate 12 is only implanted into the substrate 12 in the third region 24 when performing the second implantation step, but not implanted into the substrate 12 in the first region 20 and the fin structures 32 and 34 in the second region 22.

The ion implantation process P2 may further include a third implantation step to implant dopants with the conductivity type identical to that of the substrate 12 into the top portions of the substrate 12 in the first region 20 and the third region 24 to form the heavily doped regions (not shown). Similarly, a patterned mask (not shown) is formed to cover the second region 22 when forming the heavily doped regions in the first region 20 and the third region 24. With the shielding of the patterned mask, the dopants with the conductivity type identical to that of the substrate 12 is only implanted into the top portions of the substrate 12 in the first region 20 and the third region 24 when performing the third implantation step, but not implanted into the fin structures 32 and 34 in the second region 22.

Next, as shown in FIG. 6, a patterned mask (not shown) is used to cover the first region 20 and the third region 24, and only the second region 22 is exposed. Next, the portions of the fin structures 32 and 34 protruding from the first isolation structure 40, the second isolation structure 42 and the third isolation structure 44 are removed, so that and the top ends of the fin structures 32 and 34 are slightly concaved relative to the first isolation structure 40, the second isolation structure 42 and the third isolation structure 44. Next, a selective epitaxial growth process P3 is performed to form a plurality of epitaxial structures 36 respectively on the plurality of fin structures 32 and 34. The plurality of epitaxial structures 36 are merged with each other.

In this embodiment, when forming the epitaxial structures 36, the dopants with the conductivity type different from that of the substrate 12 may be implanted into the epitaxial structures 36 in-situ by an ion implantation process and an annealing process, so as to form the heavily doped region (not shown) in the epitaxial structures 36. In other embodiment, the ion implantation process and the annealing process may be performed after the epitaxial structures 36 are formed, so as to implant the dopants with the conductivity type different from that of the substrate 12 into the epitaxial structures 36 to form the heavily doped region (not shown) in the epitaxial structures 36. As mentioned above, it is preferable to form a patterned mask (not shown) to cover the first region 20 and the third region 24 when forming the epitaxial structures 36 and the heavily doped region in the epitaxial structures 36. With the shielding of the patterned mask, it can prevent the epitaxial structures 36 from being formed on the top surface 201 of the substrate 12 in the first region 20 and the top surface 241 of the substrate 12 in the third region 24, and the dopants with the conductivity type opposite to that of the substrate 12 are only implanted into the epitaxial structures 36 but not implanted into the top portions of the substrate 12 in the first region 20 and the third region 24. The dopant concentration of the aforementioned heavily doped region is greater than the dopant concentrations of the first well region 14 and the second well region 16. Thereby, the fabrication of the BJT 10 may be completed.

As mentioned above, in this embodiment, the BJT 10 is exemplary the PNP transistor. Therefore, the substrate 12 is the P-type substrate, the first well region 14 is the N-type well region, the second well region 16 is the P-type well region, the heavily doped region of the first region 20 is a P+ region, the heavily doped region of the epitaxial structures 36 of the second region 22 is an N+ region, and the heavily doped region of the third region 24 is a P+ region. However, the present disclosure is not limited thereto. In other embodiments, the conductivity types of the substrate 12, the first well region 14, the second well region 16, the heavily doped regions of the first region 20 and the third region 24 and the heavily doped region of the epitaxial structures 36 can be reversed, so that the BJT 10 is the NPN transistor.

In addition, in this embodiment, the heavily doped regions of the first region 20 and the third region 24 are formed before the epitaxial structures 36 are formed. In other embodiments, the heavily doped regions of the first region 20 and the third region 24 may also be formed after the epitaxial structures 36 are formed.

The aforementioned film layers, such as the isolation structures 50 and 52 and the epitaxial structure 36, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 6 and FIG. 7 at the same time. FIG. 6 is a schematic cross-sectional view showing the BJT 10 according to one embodiment of the present disclosure. FIG. 7 is a schematic top view showing the BJT 10 shown in FIG. 6. FIG. 6 is a schematic cross-sectional view taken along line A-A′ in FIG. 7. For the sake of simplification, the epitaxial structures 36 shown in FIG. 6 are omitted in FIG. 7.

The BJT 10 includes the emitter region ER, the base region BR, the collector region CR and the plurality of fin structures 32 and 34. The emitter region ER is disposed on the substrate 12. The base region BR surrounds the emitter region ER. The collector region CR surrounds the base region BR. The plurality of fin structures 32 and 34 are disposed in the base region BR and surround the emitter region ER, and the plurality of fin structures 32 and 34 fixedly extend along the first horizontal direction D1 and parallel to each other.

The BJT 10 may further include the plurality of epitaxial structures 36 respectively disposed on the plurality of fin structures 32 and 34, and the plurality of epitaxial structures 36 are merged with each other.

The plurality of fin structures 32 and 34 are only disposed in the base region BR, but not disposed in the emitter region ER and the collector region CR. That is, the base region BR is configured as a non-planar structure, and the emitter region ER and the collector region CR are configured as planar structures. In the configuration that the fin structures are also disposed in the emitter region ER and the collector region CR, although it is favorable for reducing the areas of the emitter region ER and the collector region in the top viewing angle by disposing the fin structures in the emitter region ER and the collector region CR, it is unfavorable for maintaining the ability of the emitter region ER and the collector region CR to withstand high voltages. In the present disclosure, with the fin structures 32 and 34 only being disposed in the base region BR, it can maintain the ability of the emitter region ER and the collector region CR to withstand high voltages. Meanwhile, the area of the base region BR in the top viewing angle can be reduced.

In the top view of the BJT 10, the emitter region ER includes a rectangular shape, the base region BR includes a rectangular ring, and the collector region CR includes a rectangular ring. For example, the emitter region ER may include a square shape, the base region BR may include a square ring, and the collector region CR may include a square ring, but not limited thereto. The emitter region ER, the base region BR, and the collector region CR may be arranged to include other geometric shapes. For example, the emitter region ER may include a circle, and each of the base region BR and the collector region CR may include a circular ring. In FIG. 7, the emitter region ER, the base region BR and the collector region CR may be arranged concentrically. That is, in the top view of the BJT 10, the central points of the emitter region ER, the base region BR and the collector region CR coincide with each other.

The plurality of fin structures 32 fixedly extend along the first horizontal direction D1 and are disposed above and below the emitter region ER. The plurality of fin structures 34 fixedly extend along the first horizontal direction D1 and are disposed at the left side and the right side of the emitter region ER. Thereby, the fin structures 32 and the fin structures 34 surround the emitter region ER. With the plurality of epitaxial structures 36 disposed on the fin structures 32 and 34 being merged with each other, the fin structures 32 and 34 surrounding the emitter region ER can be electrically connected with each other. Thereby, extra wires for electrically connecting the plurality of fin structures 32 and 34 can be omitted, which is beneficial to reduce the size of the BJT 10. In other embodiments, when the BJT only includes the fin structures 32 but not include the fin structures 34 (that is, no fin structures 34 are disposed at the left side and the right side of the emitter region ER), additional wires are required to connect the fin structures 32 located above the emitter region ER and the fin structures 32 located below the emitter region ER, which is unfavorable for reducing the size of the BJT.

In the plurality of fin structures 32 and 34, the length L1 of the fin structure 32 in the first horizontal direction D1 is greater than the length L2 of the fin structure 34 in the first horizontal direction D1. In the top view of the BJT 10, the left end T1 of the fin structure 32 is aligned with the left end T3 of the fin structure 34 disposed at the left side of the emitter region ER, and the right end T2 of the fin structure 32 is aligned with the right end T4 of the fin structure 34 disposed at the right side of the emitter region ER.

The BJT 10 may further include the first isolation structure 40, the second isolation structure 42 and the third isolation structure 44. The first isolation structure 40 is disposed between the emitter region ER and the base region BR, the second isolation structure 42 is disposed between the base region BR and the collector region CR, and the third isolation structure 44 is disposed between two adjacent ones of the plurality of fin structures 32 and 34.

As shown in FIG. 6, the first isolation structure 40 includes the step structure ST1, so that the top surface 401 of the first isolation structure 40 includes two horizontal surfaces instead of a single horizontal surface, and a first step difference d1 is defined between the two horizontal surfaces. In addition, the first isolation structure 40 has different heights in the vertical direction D3. The second isolation structure 42 includes a step structure ST2, so that the top surface 421 of the second isolation structure 42 includes two horizontal surfaces instead of a single horizontal surface, and a step difference d2 is defined between the two horizontal surfaces. In addition, the second isolation structure 42 has different heights in the vertical direction D3. The third isolation structure 44 does not include a step structure, so that the height of the third isolation structure 44 in the vertical direction D3 is substantially fixed.

The maximum height H1 of the first isolation structure 40 is different from the maximum height H2 of the second isolation structure 42. Herein, the maximum height H1 of the first isolation structure 40 is less than the maximum height H2 of the second isolation structure 42. Thereby, the second isolation structure 42 disposed between the base region BR and the collector region CR has a larger maximum height H2, which is beneficial to increase the breakdown voltage. With the first isolation structure 40 disposed between the emitter region ER and the base regions BR having a smaller maximum height H1, it is beneficial to maintain the injection efficiency of the emitter region ER.

The maximum height H3 of the third isolation structure 44 is less than the maximum height H1 of the first isolation structure 40, and the maximum height H3 of the third isolation structure 44 is less than the maximum height H2 of the second isolation structure 42. The maximum height H3 of the third isolation structure 44 is identical to the minimum height H5 of the first isolation structure 40 and the minimum height H6 of the second isolation structure 42. Since the height of the third isolation structure 44 in the vertical direction D3 is fixed, it can also be regarded that the minimum height (not labeled) of the third isolation structure 44 is identical to the minimum height H5 of the first isolation structure 40 and the minimum height H6 of the second isolation structure 42.

The ratio of the maximum height H1 of the first isolation structure 40 to the maximum height H2 of the second isolation structure 42 may range from 0.4 to 0.6. The ratio of the step difference d1 to the maximum height H1 of the first isolation structure 40 may range from 0.2 to 0.3. The ratio of the step difference d2 to the maximum height H2 of the second isolation structure 42 may range from 0.1 to 0.15. According to an embodiment of the present disclosure, the step difference d1 and the step difference d2 may be 300 angstroms, the maximum height H1 of the first isolation structure 40 may be 1250 angstroms, and the maximum height H2 of the second isolation structure 42 may be 2500 angstroms.

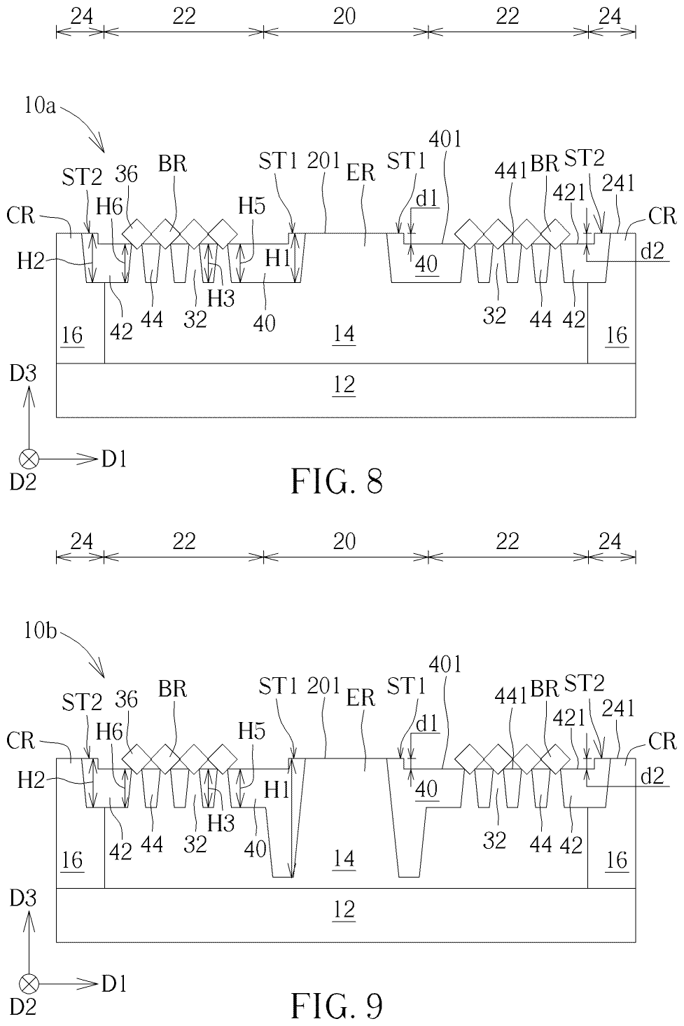

Please refer to FIG. 8, which is a schematic cross-sectional view showing a BJT 10a according to another embodiment of the present disclosure. The viewing angle of FIG. 8 is the same as that of FIG. 6. The main difference between the BJT 10a and the BJT 10 is that the maximum height H2 of the second isolation structure 42 is reduced, and the maximum height H2 of the second isolation structure 42 is identical to the maximum height H1 of the first isolation structure 40. With both the first isolation structure 40 and the second isolation structure 42 being arranged with smaller heights, it is beneficial for the BJT 10a suitable for a lower operating voltage and providing a higher current.

Please refer to FIG. 9, which is a schematic cross-sectional view showing a BJT 10b according to further another embodiment of the present disclosure. The viewing angle of FIG. 9 is the same as that of FIG. 6. The main difference between the BJT 10b and the BJT 10 is that the maximum height H1 of the first isolation structure 40 is increased, while the maximum height H2 of the second isolation structure 42 is reduced. Thereby, it is beneficial to increase the voltages applied to the emitter region ER and the base region BR.

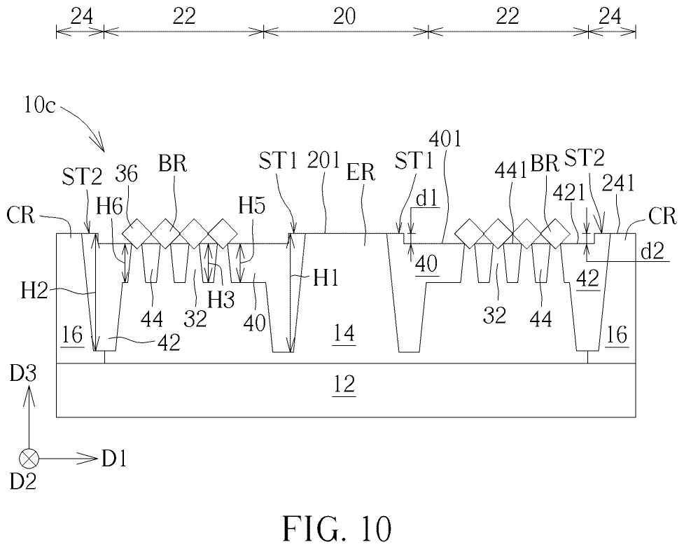

Please refer to FIG. 10, which is a schematic cross-sectional view showing a BJT 10c according to yet another embodiment of the present disclosure. The viewing angle of FIG. 10 is the same as that of FIG. 6. The main difference between the BJT 10c and the BJT 10 is that the maximum height H1 of the first isolation structure 40 is increased, and the maximum height H1 of the first isolation structure 40 is identical to the maximum height H2 of the second isolation structure 42. With both the first isolation structure 40 and the second isolation structure 42 being arranged with larger heights, it is beneficial to increase the voltages applied to the emitter region ER, the base region BR and the collector region CR.

According to the above description, in the present disclosure, the heights of the first isolation structure and the second isolation structure can be flexibly adjusted according to the applicable voltages of the emitter region, the base region and the collector region and the desired current provided by the BJT.

Compared with the prior art, in the present disclosure, the fin structures are only disposed in the base region and are not disposed in the emitter region and collector region. On one hand, it can maintain the ability of the emitter region and the collector region to withstand high voltage. On the other hand, it can reduce the area of the base region in the top view, which is beneficial to reduce the size of the BJT. In addition, with at least one of the first isolation structure disposed between the emitter region and the base region and the second isolation structure disposed between the base region and the collector region including a step structure, it is beneficial to dispose the fin structure only in the base region but not in the emitter region and collector region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bipolar junction transistor, comprising:
an emitter region disposed on a substrate;
a base region surrounding the emitter region;
a collector region surrounding the base region; and
a plurality of fin structures disposed in the base region and surrounding the emitter region, wherein the plurality of fin structures fixedly extend along a direction and parallel to each other.

2. The bipolar junction transistor of claim 1, wherein the plurality of fin structures are only disposed in the base region.

3. The bipolar junction transistor of claim 1, wherein the plurality of fin structures comprises a first fin structure and a second fin structure, and a length of the first fin structure in the direction is greater than a length of the second fin structure in the direction.

4. The bipolar junction transistor of claim 3, wherein in a top view of the bipolar junction transistor, an end of the first fin structure is aligned with an end of the second fin structure.

5. The bipolar junction transistor of claim 1, further comprising:
a plurality of epitaxial structures respectively disposed on the plurality of fin structures, wherein the plurality of epitaxial structures are merged with each other.

6. The bipolar junction transistor of claim 1, further comprising:
a first isolation structure disposed between the emitter region and the base region; and
a second isolation structure disposed between the base region and the collector region.

7. The bipolar junction transistor of claim 6, wherein a maximum height of the first isolation structure is different from a maximum height of the second isolation structure.

8. The bipolar junction transistor of claim 6, wherein a maximum height of the first isolation structure is less than a maximum height of the second isolation structure.

9. The bipolar junction transistor of claim 6, further comprising:
a third isolation structure disposed between two adjacent ones of the plurality of fin structures, wherein a maximum height of the third isolation structure is less than a maximum height of the first isolation structure, and the maximum height of the third isolation structure is less than a maximum height of the second isolation structure.

10. A bipolar junction transistor, comprising:
an emitter region disposed on a substrate;
a base region surrounding the emitter region;
a collector region surrounding the base region;
a first isolation structure disposed between the emitter region and the base region; and
a second isolation structure disposed between the base region and the collector region, wherein at least one of the first isolation structure and the second isolation structure comprises a step structure.

11. The bipolar junction transistor of claim 10, further comprising:
a plurality of fin structures, wherein the plurality of fin structures are only disposed in the base region.

12. The bipolar junction transistor of claim 10, wherein a maximum height of the first isolation structure is different from a maximum height of the second isolation structure.

13. The bipolar junction transistor of claim 10, wherein a maximum height of the first isolation structure is identical to a maximum height of the second isolation structure.

14. A method for fabricating a bipolar junction transistor, comprising:
forming an emitter region on a substrate;
forming a base region surrounding the emitter region;
forming a collector region surrounding the base region; and
forming a plurality of fin structures in the base region and surrounding the emitter region, wherein the plurality of fin structures fixedly extend along a direction and parallel to each other.

15. The method of claim 14, wherein the plurality of fin structures are only disposed in the base region.

16. The method of claim 14, wherein forming the plurality of fin structures comprises forming a first fin structure and a second fin structure, and a length of the first fin structure in the direction is greater than a length of the second fin structure in the direction.

17. The method of claim 16, wherein in a top view of the bipolar junction transistor, an end of the first fin structure is aligned with an end of the second fin structure.

18. The method of claim 14, further comprising:
forming a plurality of epitaxial structures respectively on the plurality of fin structures, wherein the plurality of epitaxial structures are merged with each other.

19. The method of claim 14, further comprising:
forming a first isolation structure between the emitter region and the base region; and
forming a second isolation structure between the base region and the collector region.

20. The method of claim 19, wherein a maximum height of the first isolation structure is different from a maximum height of the second isolation structure.
